(19) United States
(12) Patent Application Publication
(10) Pub. No.: US 2017/0261825 A1
(43) Pub. Date: Sep. 14, 2017

(54) ARRAY SUBSTRATE AND PRODUCTION METHOD AND DISPLAY APPARATUS THEREOF

(71) Applicant: BOE TECHNOLOGY GROUP CO., LTD., Beijin (CN)

(72) Inventor: Wenbo LI, Beijing (CN)

(73) Assignee: BOE TECHNOLOGY GROUP CO, LTD, Beijing (CN)

(21) Appl. No.: 15/326,002

(22) PCT Filed: Mar. 3, 2016
(86) PCT No.: PCT/CN2016/075398

§ 371 Date: Jan. 12, 2017

(30) Foreign Application Priority Data
Sep. 29, 2015 (CN) 201510632867.3

(51) Int. Cl. G02F 1/1362; H01L 27/12; G02F 1/1368

(52) U.S. Cl. CPC G02F 1/136286; G02F 1/1368; H01L 27/124; H01L 27/1262; G02F 2001/136295

(57) ABSTRACT

The disclosure provides an array substrate and a production method and display apparatus thereof. The array substrate comprises a display area, on which a plurality of grid lines and a plurality of data lines are arranged. The grid lines are arranged to cross the data lines, dividing the display area into a plurality of sub-pixel units. A set of successive grid lines among the plurality of grid lines starting from the grid line nearest to the first edge are parallel to the first edge, and a set of successive data lines among the plurality of data lines starting from the data line nearest to the second edge are parallel to the second edge.

### RELATED APPLICATIONS

The present application is the U.S. national phase entry of PCT/CN2016/075398, with an international filing date of Mar. 3, 2016, which claims the benefit of Chinese Patent Application No. 201510632867.3, filed on Sep. 29, 2015, the entire disclosures of which are incorporated herein by reference.

### TECHNICAL FIELD

The invention relates to the field of display, and in particular, to an array substrate and a production method and display apparatus thereof.

### BACKGROUND OF THE INVENTION

A liquid crystal display panel (for example, a thin film field effect transistor liquid crystal display (TFT-LCD)) has advantages of a small volume, low power consumption, no radiation and a low manufacturing cost, etc. With the development of science and technology and the improvement of people's living standards, people are no longer limited to only paying attention to the display performance of the liquid crystal display panel, and further put forward a number of requirements for other aspects of the liquid crystal display panel. For example, the display screen shape of a conventional liquid crystal display panel is generally rectangular, and to be applied on a wearable display device and meet personalized demands of users, liquid crystal display panels of other display screen shapes have occurred currently.

The display screen shape of a liquid crystal display panel is generally determined by the display area (A/A region) of its array substrate, wherein a plurality of grid lines and data lines crossing each other are arranged on the display area of the array substrate, and a plurality of sub-pixel units are divided out by the grid lines and the data lines, such that the display function of the liquid crystal display panel as a whole may be realized. Nowadays, whether for a liquid crystal display panel with a rectangular display screen and alternatively for a liquid crystal display panel with a non-rectangular display screen, both the grid lines and the data lines on its array substrate employ a perpendicularly crossing arrangement approach. However, for a liquid crystal display panel with a non-rectangular display screen as shown in FIG. 1, since the grid lines 20′ and the data lines 30′ employ a mutually perpendicular arrangement method, such that full pixel display may not be realized in edge areas of the display area 2 (pixels may not be divided out at the position of a hatched region 10′), this easily causes that saw-tooth patterns occur to a produced liquid crystal display panel at its edges.

### SUMMARY

A technical solution of the disclosure provides an array substrate comprising a display area, on which a plurality of grid lines and a plurality of data lines are arranged, the grid lines being arranged to cross the data lines, thereby dividing the display area into a plurality of sub-pixel units, the display area comprising a first edge and a second edge arranged adjacent to each other, and a third edge opposite to the first edge and a fourth edge opposite to the second edge, the grid lines being consistent with the trends of the first edge and the third edge, the data lines being consistent with the trends of the second edge and the fourth edge, wherein the first edge is not perpendicular to the second edge and alternatively at least one of them is nonlinear, a set of successive grid lines among the plurality of grid lines starting from the grid line nearest to the first edge are parallel to the first edge, and a set of successive data lines among the plurality of data lines starting from the data line nearest to the second edge are parallel to the second edge.

Preferably, grid lines other than the set of grid lines among the plurality of grid lines are parallel to the third edge.

Preferably, data lines other than the set of data lines among the plurality of data lines are parallel to the fourth edge.

Preferably, the third edge is arranged parallel to the first edge, and/or the fourth edge is arranged parallel to the second edge.

Preferably, the set of grid lines comprise all of the plurality of grid lines, and/or the set of data lines comprise all of the plurality of data lines.

Preferably, the nonlinearity is any of the following: a curve, and a polyline.

The disclosure further provides a display apparatus comprising an array substrate described above.

The disclosure further provides a production method for an array substrate, the array substrate comprising a display area, on which a plurality of grid lines and a plurality of data lines are arranged, the grid lines being arranged to cross the data lines, dividing the display area into a plurality of sub-pixel units, the display area comprising a first edge and a second edge arranged adjacent to each other, and a third edge opposite to the first edge and a fourth edge opposite to the second edge, the grid lines being consistent with the trends of the first edge and the third edge, the data lines being consistent with the trends of the second edge and the fourth edge, wherein the first edge of the array substrate is not perpendicular to the second edge and alternatively at least one of them is nonlinear, and the plurality of grid lines and the plurality of data lines are arranged in the display area in the following manner: forming in an area near to the first edge in the display area a set of grid lines parallel to the first edge, and forming in an area near to the second edge in the display area a set of data lines parallel to the second edge.

Preferably, arranging the plurality of grid lines and the plurality of data lines in the display area further comprises: forming in an area near to the third edge in the display area another set of grid lines parallel to the third edge.

Preferably, arranging the plurality of grid lines and the plurality of data lines in the display area further comprises: forming in an area near to the fourth edge in the display area another set of data lines parallel to the forth edge.

Preferably, the third edge is arranged parallel to the first edge, and/or the fourth edge is arranged parallel to the second edge.

Preferably, the set of grid lines comprise all of the plurality of grid lines, and/or the set of data lines comprise all of the plurality of data lines.

Preferably, the nonlinearity is any of the following: a curve, and a polyline.

### BRIEF DESCRIPTION OF THE DRAWINGS

FIG. 1 is a schematic diagram of an array substrate in the prior art.

FIG. 2 is a schematic diagram of a first array substrate provided by an implementation of the invention.

FIG. 3 is a schematic diagram of a second array substrate provided by an implementation of the invention.

FIG. 4 is a schematic diagram of a third array substrate provided by an implementation of the invention.

FIG. 5 is a schematic diagram of a fourth array substrate provided by an implementation of the invention.

FIG. 6 is a schematic diagram of a fifth array substrate provided by an implementation of the invention.

FIG. 7 is a schematic diagram of a sixth array substrate provided by an implementation of the invention.

FIG. 8 is a schematic diagram of the shape of a display area of an array substrate provided by an implementation of the invention.

FIG. 9 is a schematic diagram of arranging grid lines and data lines on the display area as shown in FIG. 8.

FIG. 10 is a flow chart of the production of an array substrate provided by an implementation of the invention.

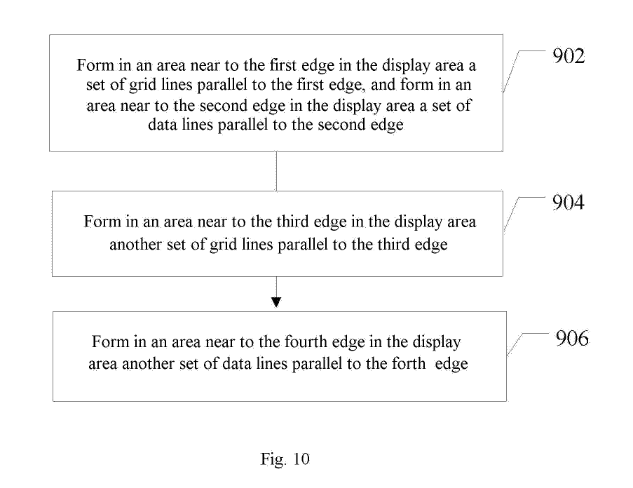

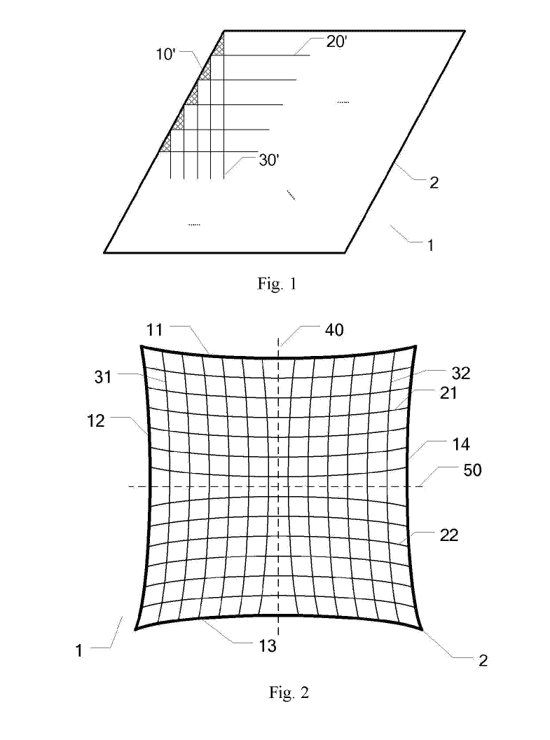

### DETAILED DESCRIPTION OF THE INVENTION

In the following specific implementations of the invention will be further described in detail in connection with the drawings and the embodiments. The following embodiments are used for illustrating the invention, but not for limiting the scope of the invention.

An implementation of the invention provides an array substrate 1 comprising a display area 2, on which a plurality of grid lines and a plurality of data lines are arranged, the grid lines being arranged to cross the data lines, thereby dividing the display area 2 into a plurality of sub-pixel units, the display area 2 comprising a first edge and a second edge arranged adjacent to each other, and a third edge opposite to the first edge and a fourth edge opposite to the second edge, the grid lines being consistent with the trends of the first edge and the third edge, the data lines being consistent with the trends of the second edge and the fourth edge, wherein the first edge is not perpendicular to the second edge and alternatively at least one of them is nonlinear, a set of successive grid lines among the plurality of grid lines starting from the grid line nearest to the first edge are parallel to the first edge, and a set of successive data lines among the plurality of data lines starting from the data line nearest to the second edge are parallel to the second edge.

For the array substrate 1 provided by the implementation of the invention, the display area 2 thereon is non-rectangular. By routing the grid lines and the data lines therein according to the edges of the display area 2, full pixel production may thereby be realized at the edges of the display area 2, and then full pixel display may be realized at the edges, which may avoid that saw-tooth patterns occur at edges of a formed non-rectangular display screen and improve the display quality of the peripheral area.

In implementations of the invention, the display area of the array substrate is non-rectangular, the first edge and the second edge may be linear, and both may be arranged non-perpendicularly, and alternatively also may be nonlinear, for example, may be a curve (e.g., an arc) and alternatively a polyline.

Reference is made to FIG. 2, which is a schematic diagram of an array substrate provided by an implementation of the invention. A display area 2 on the array substrate 1 is non-rectangular, which comprises a first edge 11 and a second edge 12 arranged adjacent to each other, a third edge 13 opposite to the first edge 11 and a fourth edge 14 opposite to the second edge 12. The first edge 11, the second edge 12, the third edge 13 and the fourth edge 14 are all curve-shaped, and on the display area 2 are arranged a plurality of grid lines and a plurality of data lines.

Therein, the grid lines of the display area 2 are divided into two sets, one set is multiple mutually parallel grid lines 21 on the upper side of a dashed line 50 and near to the first edge 11, the other set is multiple mutually parallel grid lines 22 on the lower side of the dashed line 50 and near to the third edge 13, the grid lines 21 are curve-shaped and arranged parallel to the first edge, and the grid lines 22 are curve-shaped and arranged parallel to the third edge 13.

Therein, the data lines on the display area 2 are also divided into two sets, one set is multiple mutually parallel data lines 31 on the left side of a dashed line 40 and arranged near to the second edge 12, the other set is multiple mutually parallel data lines 32 on the right side of the dashed line 40 and arranged near to the fourth edge 14, the data lines 31 are curve-shaped and arranged parallel to the second edge 12, and the data lines 32 are curve-shaped and arranged parallel to the fourth edge 14.

As shown in FIG. 2, by arranging the grid lines and the data lines according to the edges of the display area 2, full pixel production may thereby be realized at the edges of the display area 2, and then that saw-tooth patterns occur to a produced liquid crystal display panel at its edges may be avoided.

Therein, for the array substrate provided by the implementation of the invention, not only the grid lines and the data lines of the array substrate 1 may be divided into two sets as shown in FIG. 2, but they may also not be divided, and all of the grid lines on the array substrate 1 are arranged parallel to one of the edges of the display area 2, and all of the data lines are arranged parallel to another adjacent edge. For example, for the shape of the display area 2 as shown in FIG. 2, it may be possible to equally arrange all of the grid lines below the dashed line 50 to be parallel to the first edge 11, and equally arrange all of the data lines on the right side of the dashed line 40 to be parallel to the second edge adjacent to the first edge, that is, in implementations of the invention, a set of grid lines parallel to the first edge may be part of the number of grid lines on the array substrate 1, and alternatively also may be all of the grid lines, and a set of data lines parallel to the second edge may be part of the number of data lines on the array substrate 1, and alternatively also may be all of the data lines.

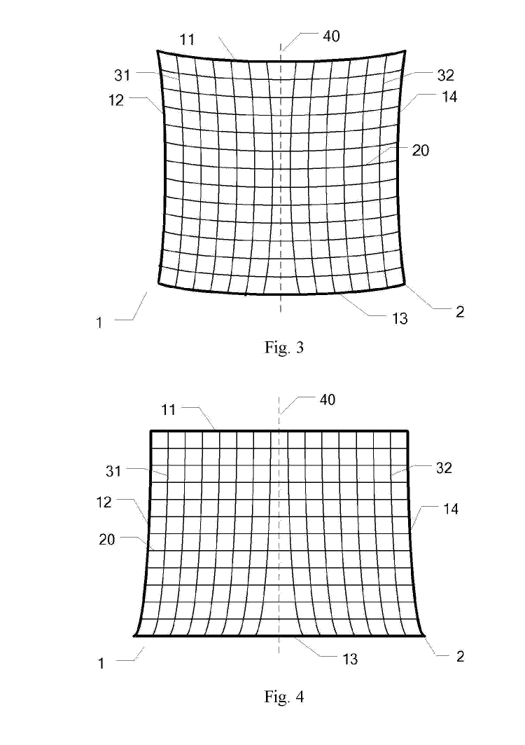

Preferably, to reduce the difference in size between sub-pixel units divided out by the grid lines and the data lines, two opposite edges of the display area 2 may be arranged in parallel. With reference to FIG. 3, FIG. 3 is a schematic diagram of a second array substrate 1 provided by an implementation of the invention. A display area 2 on the array substrate 1 is non-rectangular, which comprises a first edge 11 and a second edge 12 arranged adjacent to each other, a third edge 13 arranged opposite and parallel to the first edge 11 and a fourth edge 14 opposite to the second edge 12. The first edge 11, the second edge 12, the third edge 13 and the fourth edge 14 are all curve-shaped.

On the display area 2 are arranged a plurality of grid lines 20 and a plurality of data lines, wherein the grid lines on the display area 2 are all arranged parallel to the first edge 11, and the data lines on the display area 2 are divided into two sets, one set is multiple data lines 31 on the left side of a dashed line 40 and arranged near to the second edge 12, which are arranged parallel to the second edge 12, and the other set is multiple data lines 32 on the right side of the dashed line 40 and arranged near to the fourth edge 14, which are arranged parallel to the fourth edge 14.

As compared to the structure in FIG. 2, this implementation may reduce the number of relatively big and alternatively relatively small units of divided sub-pixel units, and further improve the display quality.

Reference is made to FIG. 4, which is a schematic diagram of a third array substrate provided by an implementation of the invention. The array substrate 1 is substantially the same as the array substrate 1 in FIG. 3, and the difference lies in that both the first edge 11 and the third edge 13 arranged opposite and parallel to each other are linear.

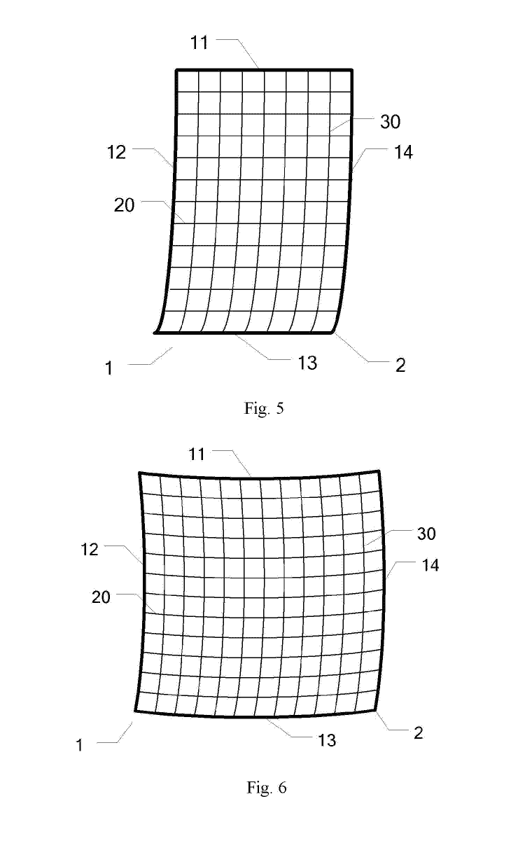

Reference is made to FIG. 5, which is a schematic diagram of a fourth array substrate provided by an implementation of the invention. A display area 2 on the array substrate 1 is non-rectangular, which comprises a first edge 11 and a second edge 12 arranged adjacent to each other, a third edge 13 arranged opposite and parallel to the first edge 11 and a fourth edge 14 arranged opposite and parallel to the second edge, wherein both the first edge 11 and the third edge 13 are linear, and both the second edge 12 and the fourth edge 14 are curve-shaped.

In the display area 2 of the array substrate 1, all of the grid lines 20 may be routed according to the first edge 11 and are arranged parallel to both the first edge 11 and the third edge 13, and all of the data lines 30 may be routed according to the second edge 12 and are arranged parallel to both the second edge 12 and the fourth edge 14.

As shown in FIG. 5, as compared to the structure in FIG. 4, this implementation may divide out sub-pixel units with a uniform size at various positions, and thereby may further improve the display quality.

Reference is made to FIG. 6, which is a schematic diagram of a fifth array substrate provided by an implementation of the invention. The array substrate 1 is substantially the same as the array substrate 1 in FIG. 5, and the difference lies in that both the first edge 11 and the third edge 13 arranged opposite and parallel to each other are curve-shaped.

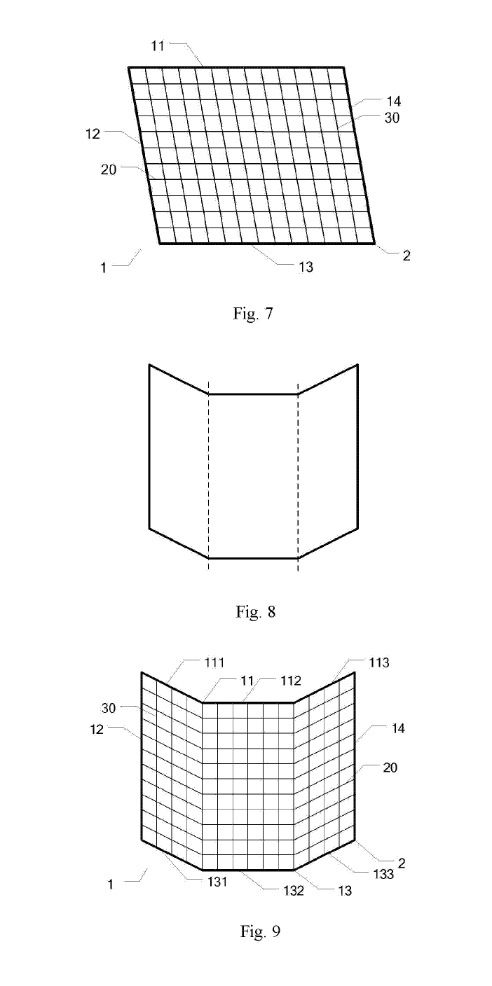

Reference is made to FIG. 7, which is a schematic diagram of a sixth array substrate provided by an implementation of the invention. A display area 2 on the array substrate 1 comprises a first edge 11 and a second edge 12 which are adjacent and non-perpendicular to each other, a third edge 13 arranged opposite and parallel to the first edge 11 and a fourth edge 14 arranged opposite and parallel to the second edge, wherein the first edge 11, the second edge 12, the third edge 13 and the fourth edge 14 are all linear, and thereby form the display area 2 of a parallelogram shape.

In the formed display area 2, all of the grid lines 20 are arranged parallel to both the first edge 11 and the third edge 13, and all of the data lines 30 are arranged parallel to both the second edge 12 and the fourth edge 14, that is, the grid lines 20 and the data lines 30 are non-perpendicularly arranged likewise, and thereby sub-pixel units with a uniform size are divided out at various positions of the display area 2.

In addition, for a display area of other irregular shape, a split design approach may be employed to divide the display area into a plurality of areas with relatively regular shapes, and then route the grid lines and the data lines according to edge shapes of the divided areas in real time. For example, for the shape of a display area 2 as shown in FIG. 8, it may be possible to split it into three parallelogram areas along the positions indicated by the dashed lines, and then arrange grid lines and data lines on it. Of course, since FIG. 8 is essentially also composed of an adjacent first edge 11 and second edge 12, a third edge 13 opposite and parallel to the first edge, and a fourth edge 14 opposite and parallel to the second edge, the existence of the polylines 11 and 13 does not affect the application of the spirit of the invention, and the arrangement approach applicable to the grid lines and the data lines in FIGS. 5-7 is likewise well applicable to the display area 2 in FIG. 8 without the need for a split step.

For example, grid lines and data lines may be arranged as depicted in FIG. 9 in the display area 2 shown in FIG. 8. In particular, the grid lines of the array substrate 1 are made to be routed according to the first edge 11 and the third edge 13, wherein both the first edge 11 and the third edge 13 are polyline-shaped, the first edge 11 comprises three linear portions, a linear portion 111, a linear portion 112 and a linear portion 113, respectively, the third edge 13 comprises corresponding three linear portions likewise, a linear portion 131 parallel to the linear portion 111, a linear portion 132 parallel to the linear portion 112 and a linear portion 133 parallel to the linear portion 113, respectively, and the formed grid lines 20 are of a polyline shape consistent with the first edge 11 and the third edge 13 likewise. The data lines of the array substrate 1 are made to be routed according to the second edge 12 and the fourth edge 14 which are parallel to each other and both linear, to form corresponding data lines 30.

In the array substrate provided by implementations of the invention, by routing the grid lines and the data lines therein according to the edges of the display area, such that the formed pixel structure matches the corresponding display screen structure to the greatest extent, the display quality of the peripheral area is thereby guaranteed.

An implementation of the invention further provides a display apparatus comprising an array substrate described above. Therein, the display apparatus provided by the implementation of the invention may be any product and alternatively component that has a display function, such as a notebook computer display screen, a liquid crystal display, a liquid crystal TV, a digital photo frame, a mobile phone, a tablet computer, etc. For example, the display apparatus may further be a wearable display device.

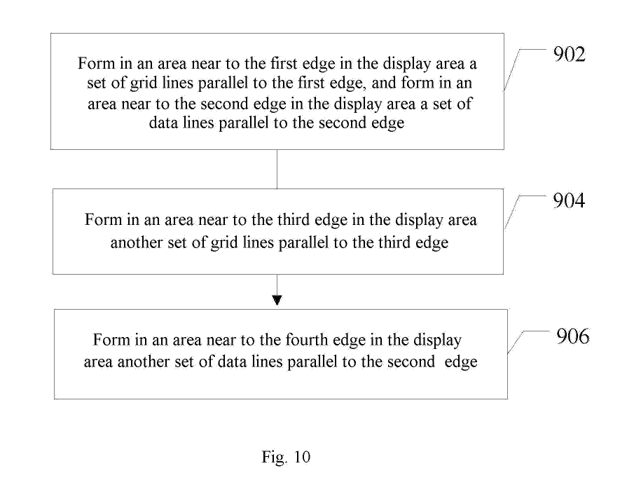

FIG. 10 shows a production method of an array substrate provided by an implementation of the invention. The array substrate 1 comprises a display area 2, on which a plurality of grid lines and a plurality of data lines are arranged, the grid lines are arranged to cross the data lines, dividing the display area 2 into a plurality of sub-pixel units, the display area 2 comprises a first edge and a second edge arranged adjacent to each other, and a third edge opposite to the first edge and a fourth edge opposite to the second edge, the grid lines are consistent with the trends of the first edge and the third edge, and the data lines are consistent with the trends of the second edge and the fourth edge, wherein the first edge of the array substrate 1 is not perpendicular to the second edge and alternatively at least one of them is nonlinear, and the plurality of grid lines and the plurality of data lines are arranged in the display area 2 in the following manner: forming in an area near to the first edge in the display area 2 a set of grid lines parallel to the first edge, and forming in an area near to the second edge in the display area 2 a set of data lines parallel to the second edge (step 902).

According to an embodiment, arranging the plurality of grid lines and the plurality of data lines in the display area 2 further comprises: forming in an area near to the third edge in the display area 2 another set of grid lines parallel to the third edge (step 904).

According to an embodiment, arranging the plurality of grid lines and the plurality of data lines in the display area 2 further comprises: forming in an area near to the fourth edge in the display area 2 another set of data lines parallel to the forth edge (step 906).

According to an embodiment, the third edge is arranged parallel to the first edge, and/or the fourth edge is arranged parallel to the second edge.

According to an embodiment, the set of grid lines comprise all of the plurality of grid lines, and/or the set of data lines comprise all of the plurality of data lines.

According to an embodiment, the nonlinearity is any of the following: a curve, and a polyline.

The foregoing implementations are only used for illustrating the invention, but not for limiting the invention. Those of ordinary skills in the related art may further make various changes and variations thereto without departing from the spirit and scope of the invention. Therefore, all equivalent technical solutions also belong to the category of the invention, and the scope of patent protection of the invention should be defined by the claims.

1. An array substrate comprising a display area, on which a plurality of grid lines and a plurality of data lines are arranged, the grid lines being arranged to cross the data lines, thereby dividing the display area into a plurality of sub-pixel units, the display area comprising a first edge and a second edge arranged adjacent to each other, and a third edge opposite to the first edge and a fourth edge opposite to the second edge, the grid lines being consistent with the trends of the first edge and the third edge, the data lines being consistent with the trends of the second edge and the fourth edge,
the first edge being not perpendicular to the second edge or at least one of them is nonlinear, a set of successive grid lines among the plurality of grid lines starting from the grid line nearest to the first edge being parallel to the first edge, and a set of successive data lines among the plurality of data lines starting from the data line nearest to the second edge being parallel to the second edge.

2. The array substrate as claimed in claim 1, wherein grid lines other than the set of grid lines among the plurality of grid lines are parallel to the third edge

3. The array substrate as claimed in claim 1, wherein data lines other than the set of data lines among the plurality of data lines are parallel to the fourth edge.

4. The array substrate as claimed in claim 1, wherein the third edge is arranged parallel to the first edge, and/or the fourth edge is arranged parallel to the second edge.

5. The array substrate as claimed in claim 1, wherein the set of grid lines comprise all of the plurality of grid lines, and/or the set of data lines comprise all of the plurality of data lines.

6. The array substrate as claimed in claim 1, wherein the nonlinearity is any of the following: a curve, and a polyline.

7. A display apparatus, characterized by comprising an array substrate as claimed in claim 1.

8. A production method for an array substrate, the array substrate comprising a display area, on which a plurality of grid lines and a plurality of data lines are arranged, the grid lines being arranged to cross the data lines, dividing the display area into a plurality of sub-pixel units, the display area comprising a first edge and a second edge arranged adjacent to each other, and a third edge opposite to the first edge and a fourth edge opposite to the second edge, the grid lines being consistent with the trends of the first edge and the third edge, the data lines being consistent with the trends of the second edge and the fourth edge,
the first edge of the array substrate being not perpendicular to the second edge or at least one of them is nonlinear, and the plurality of grid lines and the plurality of data lines are being arranged in the display area in the following manner:
forming in an area near to the first edge in the display area a set of grid lines parallel to the first edge, and forming in an area near to the second edge in the display area a set of data lines parallel to the second edge.

9. The production method for an array substrate as claimed in claim 8, wherein arranging the plurality of grid lines and the plurality of data lines in the display area further comprises:
forming in an area near to the third edge in the display area another set of grid lines parallel to the third edge.

10. The production method for an array substrate as claimed in claim 8, wherein arranging the plurality of grid lines and the plurality of data lines in the display area further comprises:
forming in an area near to the fourth edge in the display area another set of data lines parallel to the fourth edge.

11. The production method for an array substrate as claimed in claim 8, wherein the third edge is arranged parallel to the first edge, and/or the fourth edge is arranged parallel to the second edge.

12. The production method for an array substrate as claimed in claim 8, wherein the set of grid lines comprise all of the plurality of grid lines, and/or the set of data lines comprise all of the plurality of data lines.

13. The production method for an array substrate as claimed in claim 8, wherein the nonlinearity is any of the following: a curve, and a polyline.

14. A display apparatus, characterized by comprising an array substrate as claimed in claim 2.

15. A display apparatus, characterized by comprising an array substrate as claimed in claim 3.

16. A display apparatus, characterized by comprising an array substrate as claimed in claim 4.

17. A display apparatus, characterized by comprising an array substrate as claimed in claim 5.

18. A display apparatus, characterized by comprising an array substrate as claimed in claim 6.
